(19) United States
(12) Patent Application Publication
(10) Pub. No.: US 2026/0235458 A1
(43) Pub. Date: Aug. 13, 2026

(54) FIXED-POINT IMPEDANCE-TO-FREQUENCY CONVERTERS

(71) Applicant: Washington University, St. Louis, MO (US)

(72) Inventors: Shantanu CHAKRABARTTY, St. Louis, MO (US); Weilun LI, St. Louis, MO (US)

(21) Appl. No.: 19/529,877

(22) Filed: Feb. 4, 2026

Related U.S. Application Data
(60) Provisional application No. 63/753,668, filed on Feb. 4, 2025.

(51) Int. Cl. G01L 1/20; G01L 1/14; H03K 17/60

(52) U.S. Cl. CPC G01L 1/20; G01L 1/14; H03K 17/60

(57) ABSTRACT

A method of converting an impedance of a transducer to a frequency includes providing a first voltage to an oscillator circuit, the first voltage having a known relationship to a second voltage, generating a square wave signal with the oscillator circuit, the square wave signal having a frequency determined at least in part by the first voltage and opening and closing a switch coupled across a first terminal and a second terminal of the transducer in response to the square wave signal generated by the oscillator circuit to vary the second voltage as a function of the impedance of the transducer. The first terminal of the transducer is connected to a fixed third voltage.

### CROSS REFERENCE TO RELATED APPLICATIONS

This application claims priority to U.S. Provisional Patent Application No. 63/753,668, filed Feb. 4, 2025, which is hereby incorporated by reference in its entirety.

### STATEMENT REGARDING FEDERALLY SPONSORED RESEARCH & DEVELOPMENT

This invention was made with government support under HD105905 awarded by the National Institutes of Health. The government has certain rights in the invention.

### BACKGROUND

The present disclosure generally relates to single and multi-channel fixed-point impedance-to-frequency converters, as an alternate approach for measuring changes in electrical impedance.

Smart wearable sensors have gained considerable attention in several fields that include human health monitoring, human-machine interface, and motion detection. These soft and flexible sensors can be comfortably and securely attached to the human body surface while converting physical signals into electrical signals. However, in traditional wearable sensors for detecting variations in strain or pressure, the transduction mechanism involves a change in only one of their electrical properties, its resistance or its capacitance, in response to an external mechanical stimulus. In this regard, a wearable sponge transducer has been reported that can produce changes in both resistance and capacitance in response to the external mechanical stimulus.

FIG. 1A illustrates the cross-sectional view of a known poly(3, 4-ethylene dioxythiophene) polystyrene sulfonate (PEDOT: PSS) sponge transducer where the air gaps within the transducer contribute towards the total capacitance CL measured across the transducer. The resistance across the transducer RL on the other hand is determined by the density of the conductive polymer PEDOT: PSS. When the transducer is subjected to a mechanical strain, as shown in FIG. 1B, both the resistance and capacitance change but in opposite directions respectively. This implies that an impedance measurement method that weighs the change in RL and CL appropriately (opposite sensitivity) can achieve significantly higher sensitivity than just measuring the resistance or the capacitance alone. Another challenge in n scaling the number of wearable/flexible sensors is that each of the sensor units needs to be ultra-low-power and each sensor can be individually addressed so that the information can be retrieved. In a conventional implementation, the information is multiplexed on a physical (wire or body) channel or a virtual (packet-switched) channel. This requires the integration of batteries on the sensor or the use of remote powering, both of which require ultra-low-power impedance sensing and communication circuits. Additional details on such sponge transducers can be found in “A Soft Sponge Sensor for Multimodal Sensing and Distinguishing of Pressure, Strain, and Temperature,” ACS Applied Materials & Interfaces, vol. 14, no. 7, pp. 9570-9578, 2022 and “Stretchable Sponge Electrodes for Long-Term and Motion-Artifact-Tolerant Recording of High-Quality Electrophysiologic Signals,” ACS Nano, vol. 16, no. 8, pp. 11792-11801, 2022, both of which are incorporated herein by reference in their entireties.

In literature, the most common approach for measuring impedance follows a topology shown in FIG. 2. A voltage controlled current source Gₘ, drives the sensor impedance Z_{L} resulting in a voltage V_{L} across the sensor. V_{L} is then demodulated by M using the source signal V_{OSC} as a reference. Using both coherent and non-coherent approaches the impedance can be measured at different frequencies Fₒᵤₜ as shown in FIG. 3. Generally, the frequency at which the impedance is measured Fₒᵤₜ is chosen a-priori or swept over a pre-determined range; however, the optimal operating frequency could vary based on the sensor dimensions and the environmental conditions (sweat and dry conditions). Also, to minimize the power dissipation and for safety considerations, the impedance Z_{L} is driven using small currents, hence an amplifier is required to amplify the change in voltage V_{L}. An Analog-to-digital converter (ADC) and serial peripheral interface (SPI) interfaces are used for extracting the impedance changes and for signal transmission and post-processing. However, if the objective is to measure the change in the magnitude of the impedance |Z_{L}| rather than its resistive or reactive components, then the number of modules (and hence power) can be significantly reduced. Also, note that the conventional approach shown uses an open-loop configuration, implying that any noise injected into the internal nodes has to be compensated using post-processing techniques

Electrical Impedance Tomography (EIT) is a non-invasive technique that creates images by mapping changes in the electrical conductivity of tissues. It does so by passing small electrical currents through the body and measuring the resulting voltage differences on the surface. This method generates functional data about the tissues being examined. EIT works by placing electrodes around a targeted body area, applying currents, and then constructing images based on how electricity traverses various types of tissue, such as distinguishing between air and fluid. There is a need for more compact EIT systems for use in biomedical research. Optical microscopy, a standard tool for examining cells and tissues, can be invasive and may disrupt the physiological conditions under study. In contrast, EIT offers a non-invasive alternative that can provide crucial insights into cell growth and reactions. This makes it a significant tool for advancing precision medicine and drug development. The most common known approach for EIT follows the topology shown in FIG. 3.

This background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect of this disclosure is a impedance-to-frequency converter (ITFC) circuit without a sinusoidal current source. The ITFC circuit include a current reference circuit including a first reference terminal and a second reference terminal, an oscillator circuit including an oscillator output and an input connected to the first reference terminal of the current reference circuit, and a switch circuit including a switch input connected to the oscillator output. The second reference terminal is connected to a first ITFC terminal configured for connection to a first terminal of a transducer, and a first voltage at the first reference terminal has a known relationship with a second voltage at the second reference terminal. The oscillator circuit output is configured to output an output signal whose frequency is determined at least in part on the first voltage at the first reference terminal. The switch circuit coupled across the first terminal of the transducer and a second terminal of the transducer and configured to open and close a connection between the first terminal of the transducer and the second terminal of the transducer in response to the output signal from the oscillator circuit. The second voltage at the second reference terminal of the current reference circuit varies based on whether the connection between the first terminal of the transducer and the second terminal of the transducer in the switch circuit is closed or open and one or both of a resistance and a capacitance of the transducer.

Another aspect of this disclosure is a method of converting an impedance of a transducer to a frequency. The method includes providing a first voltage to an oscillator circuit, the first voltage having a known relationship to a second voltage, generating a square wave signal with the oscillator circuit, the square wave signal having a frequency determined at least in part by the first voltage and opening and closing a switch coupled across a first terminal and a second terminal of the transducer in response to the square wave signal generated by the oscillator circuit to vary the second voltage as a function of the impedance of the transducer. The first terminal of the transducer is connected to a fixed third voltage.

Another aspect of the disclosure is an EIT system, wherein the ITFC circuit is multiplexed across multiple electrodes and measuring impedance.

Yet another aspect of the disclosure is an EIT system, wherein different electrode pairs are connected to a separate ITFC circuit which wirelessly transmits the information using frequency-division multiplexing.

Various refinements exist of the features noted in relation to the above-mentioned aspects. Further features may also be incorporated in the above-mentioned aspects. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

The following figures illustrate various aspects of the disclosure.

FIG. 1A is a cross-sectional view of a known poly(3, 4-ethylene dioxythiophene) polystyrene sulfonate (PEDOT: PSS) sponge transducer.

FIG. 1B is a view of the transducer in

FIG. 1A subjected to a mechanical strain.

FIG. 2 is a simplified diagram of a known topology used for measuring impedance.

FIG. 3 graphs impedance measured at different frequencies Fₒᵤₜ using the topology shown in FIG. 2.

FIG. 4 is a simplified diagram of an impedance-to-frequency converter (ITFC) circuit topology used for measuring impedance according to the present disclosure.

FIG. 5 is a transfer characteristic of the topology shown in FIG. 4 where a fixed operating point (V_{L}, Fₒᵤₜ) is determined by ZI.

FIG. 6 is another embodiment of an ITFC circuit according to the present disclosure.

FIG. 7 is a timing diagram corresponding to a switch in the ITFC circuit shown in FIG. 6.

FIG. 8 is another embodiment of an ITFC circuit according to the present disclosure.

FIG. 9 is an oscillator circuit for the ITFC circuit shown in FIG. 8.

FIG. 10 is a current reference circuit for the ITFC circuit shown in FIG. 8.

FIG. 11 is a switching circuit for the ITFC circuit shown in FIG. 8.

FIG. 12 is an active shield module for the ITFC circuit shown in FIG. 8.

FIG. 13 is a photograph of an assembled ITFC board next to a U.S. quarter for scale.

FIG. 14 shows the measured transfer characteristic of the ITFC shown in FIG. 8 between the output frequency Fₒᵤₜ and the tunable voltage V0 for three different values of the parallel combination of RL and CL.

FIG. 15 is a graph of resistance and capacitance of a transducer equivalent circuit as a function of the output frequency of the ITFC shown in FIG. 8.

FIG. 16 is an equivalent circuit for representing a sponge transducer

FIG. 17 is a graph of resistance of a transducer equivalent circuit as a function of the output frequency of the ITFC shown in FIG. 8 when capacitance was held constant.

FIG. 18 is a graph of capacitance of a transducer equivalent circuit as a function of the output frequency of the ITFC shown in FIG. 8 when resistance was held constant.

FIG. 19 is a pair of photographs of a sponge transducer positioned on a subject's wrist for Radial Pulse Sensing using the ITFC shown in FIG. 8.

FIG. 20 plots the recorded waveform for the setup in FIG. 19 showing pulse signals corresponding to the subject's heartbeat when measuring just RL and when measuring RL and CL.

FIG. 21 shows two views of the placement of the sponge transducer on a human finger joint in a straight position.

FIG. 22 shows two views of the placement of the sponge transducer on the same human finger joint shown in FIG. 21, but in a bent position.

FIG. 23 is a graph of the frequency of the output signal of the ITFC shown in FIG. 8 as a function of time when connected to the sponge transducer while the subject moves between the positions shown in FIG. 20 and FIG. 21.

FIG. 24 is an illustration of a first-order derivative of the results shown in FIG. 23.

FIG. 25 is a view of the placement of two sponge transducers on two human finger joints in a first position.

FIG. 26 is a view of the placement of the two sponge transducers on the same two human finger joints as shown in FIG. 25, but in a second position.

FIG. 27 is a power spectrum density plot of the t multiplexed signal produced by two ITFC circuits connected to the two sponge transducers in FIGS. 25 and 26.

FIG. 28 is a plot of the frequencies of two sections of the output from the two ITFC circuits connected to the two sponge transducers in FIGS. 25 and 26 when the two types of motion shown in FIGS. 25 and 26 were performed.

FIG. 29 is a simplified diagram of a micro-electrical impedance tomography (EIT) system including an ITFC according to the present disclosure.

FIG. 30 is a photograph of a prototype micro-EIT system based on the system shown in FIG. 29 which has been developed using commercial-off-the-shelf (COTS) chipsets.

FIG. 31 is another photograph of the prototype micro-EIT system shown in FIG. 30.

FIG. 32 is a block diagram of an example computing device 3300 that may be used in connection with the ITFCs of the present disclosure.

Corresponding reference characters indicate corresponding parts throughout the drawings.

### DETAILED DESCRIPTION

The present disclosure is based, at least in part, on the development of a novel impedance-to-frequency converter (ITFC) for use with a transducer that changes its resistance and capacitance in response to mechanical deformation or pressure. Some embodiments of the ITFC are low-power or ultra-low power devices. The example ITFCs may be used, for example, in wearable devices, implantable devices, in electrical impedance tomography applications, or in any other suitable device or application. The example embodiments of the ITFC include a feedback configuration comprising a voltage-controlled relaxation oscillator and a proportional-to-temperature (PTAT) current reference that sets the oscillation frequency according to the impedance of the transducer, the impedance of the sample being analyzed, and the input signal.

The oscillation frequency of the ITFC can be programmed to facilitate different sensors communicating simultaneously over a common channel (physical wire or virtual wireless channel) using frequency-division multiplexing. Thus, some embodiments comprise a low-power impedance-to-frequency converter for frequency-multiplexed wearable sensors.

ITFC is a different approach for impedance measurement than conventional approaches. Various embodiments generally use frequency locking and frequency counting, which may make the implementation more sensitive and energy efficient. A high-speed frequency counting feature is common in most microcontrollers, so ITFC can be directly integrated with many commercial-off-the-shelf (COTS) chipsets.

In single-channel embodiments, the ITFC is a good choice for measurement using multi-modal transducers where both the resistance and capacitance changes in response of the external stimuli. AS will be shown below, ITFC automatically adjusts its response so as to achieve a higher sensitivity compared to measuring resistance and capacitance independently.

For multi-channel embodiments, the ITFC can be used for, among other things, electrical impedance tomography (EIT), where the objective is to measure dynamical changes in biological impedances. In this embodiment, a multiplexer is used that switches the ITFC to measure impedance across different electrodes.

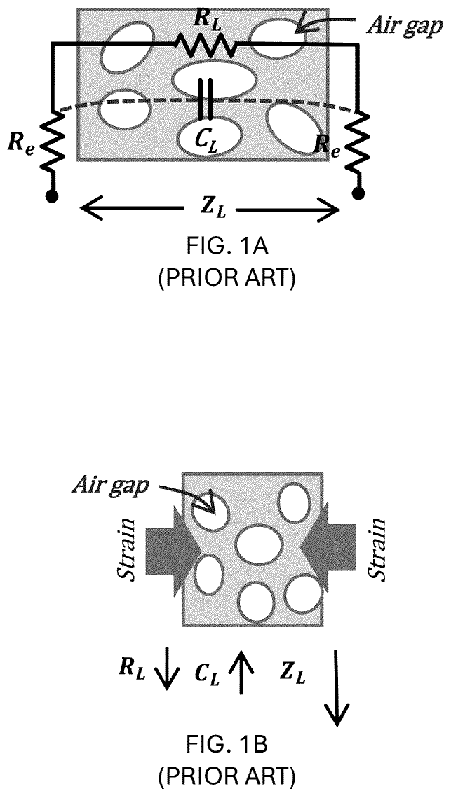

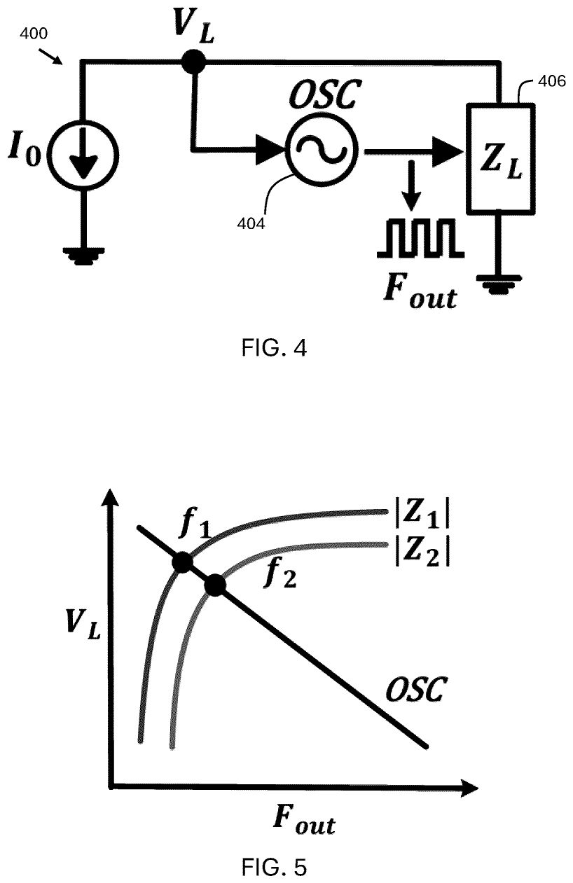

FIG. 4 is a simplified diagram of an ITFC 400 used for measuring impedance according to the present disclosure. The ITFC 400 uses a voltage-controlled oscillator 404 in a feedback configuration to modulate the impedance of a transducer 406 attached to the ITFC. In the example embodiment, the transducer is a sponge transducer such as the transducer shown in FIGS. 1A and 1B. In other embodiments, the transducer 406 is any transducer that changes its resistance and/or capacitance in response to mechanical deformation or pressure. This configuration of the ITFC 400 sets the frequency Fₒᵤₜ such that on average, a constant current I₀ can be driven through the sensor. This is equivalent to a transfer characteristic shown in FIG. 5 where the fixed operating point (V_{L}, Fₒᵤₜ) is determined by Z_{L}. The fixed-point frequency Fₒᵤₜ can be tuned such that when multiple sensors are used, the frequency output could directly be used to multiplex/communicate the measured information across a common channel. Combining the impedance sensing feature with the information multiplexing feature may reduce the form factor, improve the energy-efficiency, and/or make the proposed topology scalable across a large number of wearable sensors.

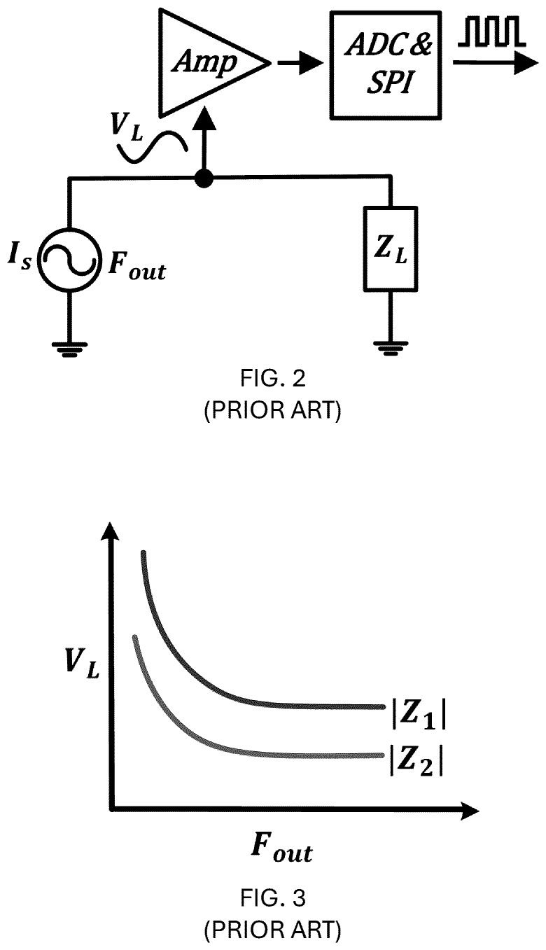

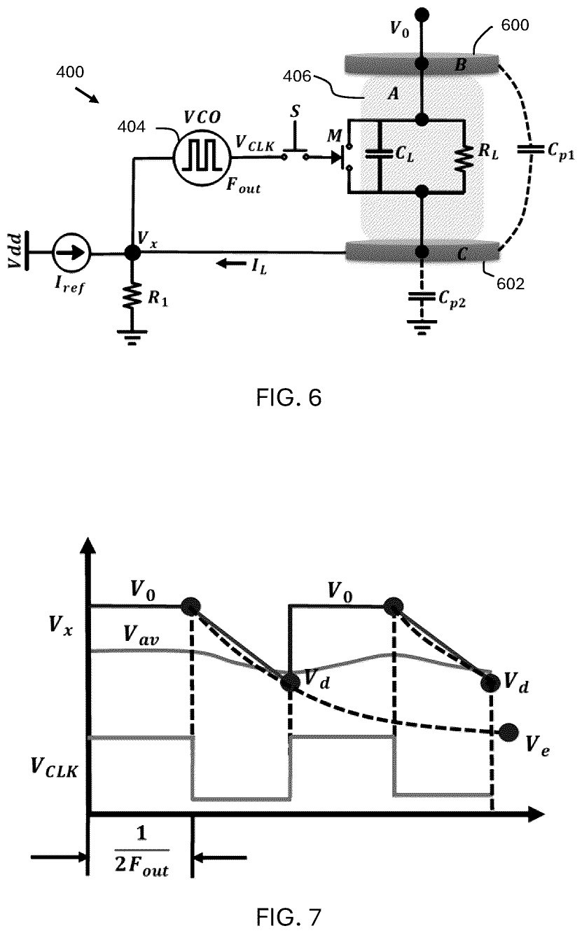

An equivalent circuit describing the operation of the ITFC 400 is shown in FIG. 6 where the transducer 406 is placed between two metallic junctions 600 and 602. Junction 600 is connected to a voltage V₀ and the junction 602 is used for sensing the load current I_{L}. To simplify the analysis, it is assumed that the transducer equivalent circuit is a parallel combination of R_{L} and C_{L}. A combination of the bias current I_{ref} and a biasing resistor R₁ generates a change in the voltage Vₓ in response to the change in the load current I_{L}. The voltage Vₓ then modulates the frequency Fₒᵤₜ of the clock signal V_{CLK} generated by a voltage-controlled oscillator (VCO) which drives the switch M through an enable switch S. Note that the switch S is used to disable the feedback loop in which case the frequency Fₒᵤₜ (in its steady state) is determined only by R_{L}. For the sake of completeness, in FIG. 2(a) we have also shown the parasitic capacitances Cₚ₁ and Cₚ₂ which will be ignored for the analysis below. A linear model is assumer for the VCO where Fₒᵤₜ is related to its input voltage Vᵢₙ according to

$${F}_{out} = - α {V}_{in} + β \qquad ( 1 )$$

where α and β are constant design parameters. These coefficients may be determined experimentally as will be shown below.

When the switch M is ON, the transducer 406 is effectively short-circuited, hence the voltage Vₓ=V₀. When the switch M is OFF, the load current I_{L} is determined by both the current flowing through R_{L} and the discharge current through C_{L}. Applying Kirchhoff's current law at node Vₓ leads to

$${I}_{ref} + \frac{{V}_{0} - {V}_{x}}{{R}_{L}} + {C}_{L} \frac{d ( {V}_{0} - {V}_{x} )}{dt} = \frac{{V}_{x}}{{R}_{1}} \qquad ( 2 )$$

which under steady-state (equilibrium) condition would let Vₓ converge to a potential Vₑ

$${V}_{e} = \frac{{V}_{0} {R}_{1} + {I}_{ref} {R}_{1} {R}_{L}}{{R}_{1} + {R}_{L}} . \qquad ( 3 )$$

This is depicted in FIG. 7 which shows a timing diagram corresponding to the switch M which is periodically turned ON and OFF by V_{CLK} according to a frequency Fₒᵤₜ. However, if Fₒᵤₜ>>1/R_{L}C_{L}, then the differential equation 2 can be linearized such that Vₓ discharges only to a non-equilibrium potential V_{d}, as shown in FIG. 7. Non-equilibrium-based analysis may be used for designing multi-channel data acquisition systems. After linearization, the equation 2 can be approximated as

$${I}_{r e f} {R}_{L} + {V}_{0} ( 1 + \frac{1}{{ω}_{1} T} ) = {V}_{d} ( 1 + \frac{{R}_{L}}{{R}_{1}} + \frac{1}{{ω}_{1} T} ) \qquad ( 4 )$$

where ω1 and the sampling period T are given by

$${ω}_{1} = \frac{1}{{R}_{L} {C}_{L}} , T = \frac{1}{2 {F}_{out}} \qquad ( 5 )$$

Using the linearized equation 4 and assuming a 50% duty-cycle, the average voltage V̅ₓ̅ can be estimated as

$${V}_{x} = \frac{3 {V}_{0} + {V}_{d}}{4} = \frac{{V}_{0}}{4} ( 3 + \frac{A}{B} ) + \frac{{I}_{ref} {R}_{L}}{4 B} \qquad ( 6 )$$

$$where ,$$

$$A = 1 + \frac{1}{{ω}_{1} T} \qquad ( 7 )$$

$$B = 1 + \frac{{R}_{L}}{{R}_{1}} + \frac{1}{{ω}_{1} T} . \qquad ( 8 )$$

Assuming that the VCO frequency Fₒᵤₜ tracks V̅ₓ̅, using equation 1 leads to

$$\begin{matrix}{F}_{out} = - α \overline{{V}_{x}} + β \\ = - ( \frac{3}{4} + \frac{A}{4 B} ) α {V}_{0} + \frac{α}{4 B} {I}_{ref} {R}_{L} + β\end{matrix} \qquad ( 9 )$$

Equation 9 is validated below using experimental results and will be used for determining the VCO coefficients α and β. Equation 9 also shows the dependence of Fₒᵤₜ on load resistance, R_{L} and C_{L} through the parameters A and B. The equation is used to conduct sensitivity analysis whereby the change ΔFₒᵤₜ can be written as

$$Δ {F}_{out} = \frac{\partial {F}_{out}}{\partial {R}_{L}} Δ {R}_{L} + \frac{\partial {F}_{out}}{\partial {C}_{L}} Δ {C}_{L} \qquad ( 10 )$$

$$where$$

$$\frac{\partial {F}_{out}}{\partial {R}_{L}} \approx - α {V}_{0} ( \frac{{C}_{L}}{4 B} - \frac{{AC}_{L}}{4 {B}^{2}} ) - \frac{α}{4 {B}^{2}} {I}_{ref} {R}_{L} {C}_{L} + \frac{α}{4 B} {I}_{ref} \qquad ( 11 )$$

$$\frac{\partial {F}_{out}}{\partial {C}_{L}} \approx - α {V}_{0} ( \frac{{R}_{L}}{4 B} - \frac{{AR}_{L}}{4 {B}^{2}} ) - \frac{α}{4 {B}^{2}} {I}_{ref} {R}_{L}^{2} \qquad ( 12 )$$

Equation 12 shows that the sensitivity to C_{L} improves as R_{L} increases, hence the proposed modality can be used for a wide range of transducers with different internal resistances. For low-resistance transducers (like metallic strain-gauges) the proposed architecture would be more sensitive to resistance changes, whereas for high-resistance transducers (like ferror-electric transducers) the proposed architecture would rely on changes in capacitances. For wearable sponge-transducers, both the modalities are combined to achieve higher sensitivity as will be shown using experimental results.

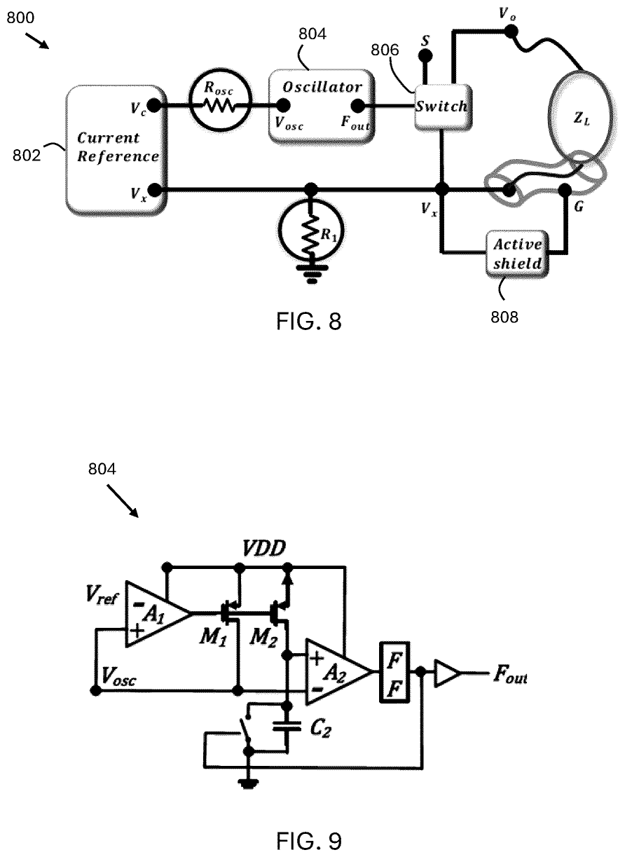

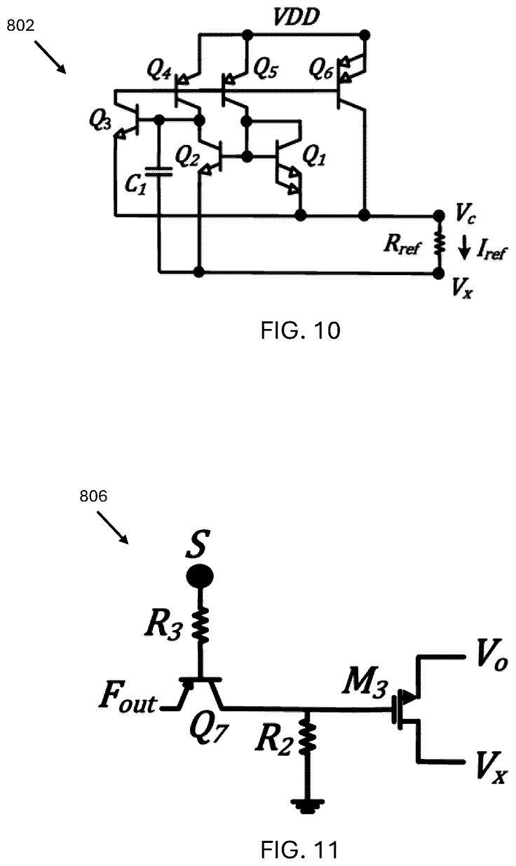

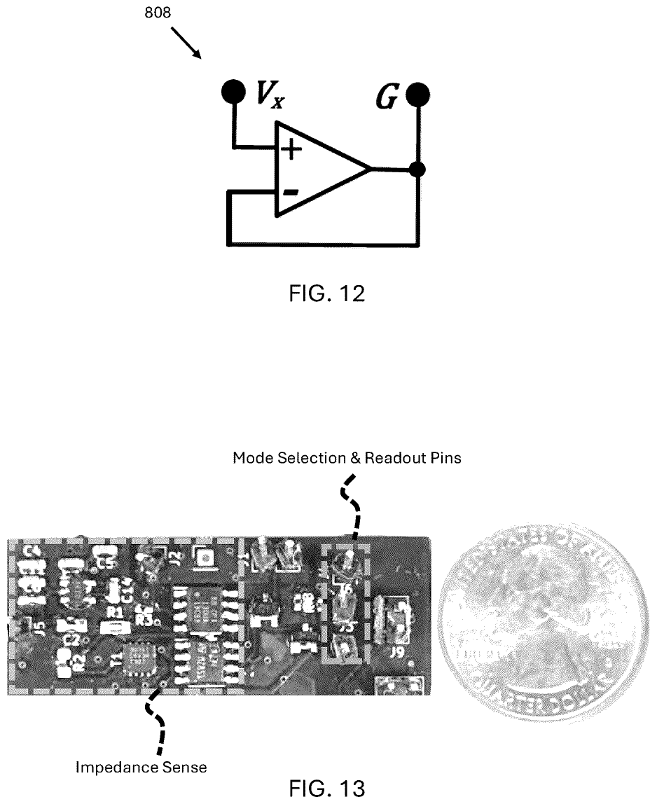

The system structure shown in FIG. 6 was implemented using the ITFC circuit 800 shown in FIG. 8. The circuit 800 includes a current reference circuit 802, an oscillator circuit 804, a switch circuit 806, and an active shield module 808. The oscillator circuit 804 was implemented using a relaxation oscillator, shown in FIG. 9 where the output frequency Fₒᵤₜ is determined by the resistor R_{osc} and the voltage V_{c}. The current reference circuit 802 was implemented using a bipolar transistor-based Proportional to Absolute Temperature (PTAT) circuit as shown in FIG. 10. I_{ref} is determined by the resistor R_{ref}, which sets the constant potential difference between the voltages V_{c} and Vₓ. The switching circuit 806 in the converter was implemented using a combination of a bipolar and an nMOS transistor shown in FIG. 11. The active shield module of the ITFC circuit 800 comprises a buffer, as shown in FIG. 12. The active shield module 808 is used to cancel out the parasitic capacitances Cₚ₁ and Cₚ₂ (shown in FIG. 6). This facilitates the output frequency Fₒᵤₜ being determined only by the load impedance Z_{L}. FIG. 13 is a photograph of an assembled ITFC board next to a U.S. quarter for scale. The assembled ITFC board integrates different commercial-off-the-shelf (COTS) chipsets implementing each of the circuit modules in FIGS. 9-12. An integrated circuits approach may be used to achieve even more significant miniaturization of the system, but because the form-factor of the overall system is typically dictated by the size of the transducer and the battery powering the system, the COTS approach provides a small enough package for many applications. Furthermore, the COTS implementation of the current reference circuit 802, the oscillator circuit 804, and the active shield module 808are highly optimized for energy efficiency while achieving high reliability. In the prototype implementation, the current reference circuit 802 was implemented using the LM234 chipset from Texas Instruments, and the oscillator circuit 804 was implemented using the TS3006 chipset from Silicon Lab. Table I below summarizes the system specification of the assembled prototype which achieves an overall power dissipation (without the active shield circuit) of less than 28 μW.

TABLE I
MEASURED SYSTEM SPECIFICATION

| Parameter | Value | |
|---|---|---|
| Supply Voltage | 3.3 | V |
| Current Consumption | 9.2 | μA |
| Form Factor | 10 | cm² |
| Output Frequency Range | 3 kHz-108 kHz | |
| Power Dissipation | 27.6 | μW |

A constructed implementation of the ITFC circuit 800 like the constructed ITFC board shown in FIG. 13 was subjected to testing using controllable circuit equivalents of the transducer 406. For the measurement results, the biasing current I_{ref} was chosen to be 9.4 μA, which sets an upper limit on the current flowing through the transducer impedance Z_{L} in FIG. 8. This feature is important for ensuring the safety of the proposed circuit when used for wearable applications.

Model Characterization—Initial measurements were designed to determine the VCO coefficients α and β in the equation 1. Z_{L} was set by choosing different values of R_{L} and C_{L}, and the voltage V₀ was swept. A Keithley DAQ6510 data acquisition system was used to acquire the output of the VCO and the frequency Fₒᵤₜ was estimated over a measurement window of 20 ms.

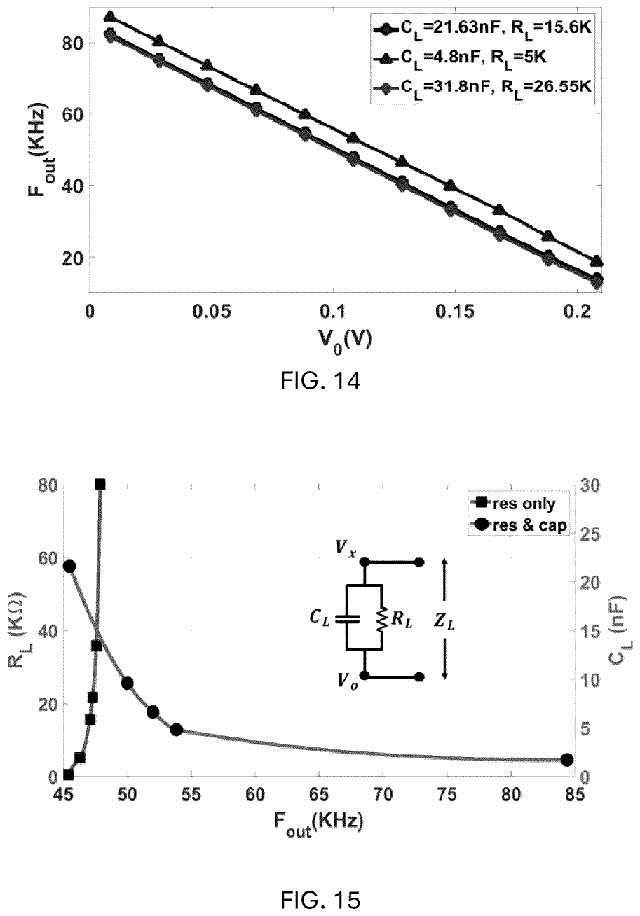

V₀ was varied between 0.01 V to 0.21 V at an increment of 0.02 V. FIG. 14 shows the measured transfer characteristic between the output frequency Fₒᵤₜ and the tunable voltage V₀ for three different values of the parallel combination of R_{L} and C_{L} (shown in FIG. 6). The results conform to the model described by equation 9 where the ratio A/B≈1 and the VCO parameters are estimated to be α=3.43×10⁵ Hz/V and β=8.2×10⁴ Hz. These parameters can be used to further validate the measured response in the subsequent experiments.

Parallel RC Impedance—For the next set of experiments, the external voltage source V₀ was fixed to 0.11 V and the equivalent circuit shown in FIG. 15 was used to represent the transducer 406. Each measurement comprised two modes: (a) a mode when the switch S (FIG. 8) was turned OFF; and (b) a mode when S was turned ON. Note that when the switch is OFF, the frequency output is only a function of the resistance R_{L}, whereas, in the ON state, the frequency output is both a function of R_{L} and C_{L} determined by the equation 10. Keeping S OFF, R_{L} was systematically varied from 300 Ω to 80 kΩ. Note that in this modality (S OFF), the load C_{L} does not affect the measurements. The results presented in FIG. 15 clearly show a monotonic relationship between Fₒᵤₜ and R_{L}. Fₒᵤₜ shows a saturation characteristic according to the relation Fₒᵤₜ≈R_{L}/(C_{L}+R_{L}), which is the asymptotic behavior the equation 11.

When the switch S is turned ON, Fₒᵤₜ is a function of both R_{L} and C_{L}. For the next experiment, we set R_{L}=14.67 kΩ, while varying C_{L} from 1.66 nF to 21.63 nF. The measured results are shown in FIG. 5 where Fₒᵤₜ varies inversely with respect to C_{L}. This matches the model given by the equation 5 where the parameter B varies proportionally to C_{L}.

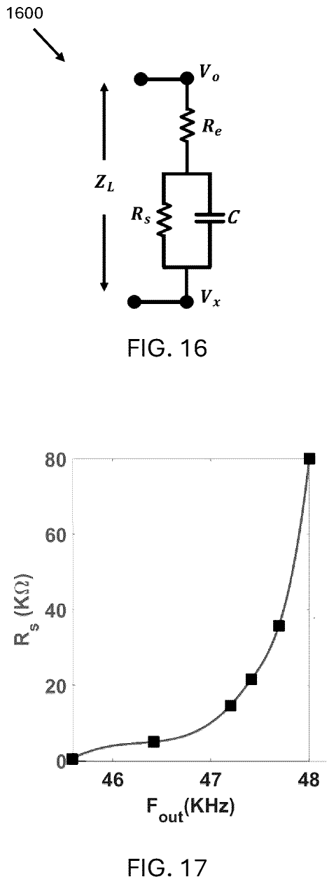

Sponge Transducer Equivalent Circuit Model—For the next experiment, an equivalent circuit 1600 model of the sponge transducer 406 as shown in FIG. 16 was used. The equivalent circuit comprises the parallel resistance (Rₛ) and capacitance (C) in series with the resistance Rₑ which models the contact resistance. The value of Rₑ was fixed to 353 Ω while modifying the values of Rₛ and C, which models the compressive or tensile strain applied to the transducer 406. Following the experimental procedure described above, the system was configured in the resistance-only sensing mode or the switch S being OFF.

Specifically, C was set as a constant value of 21.63 nF while varying Rₛ from 300 Ω to 80 kΩ. The recorded frequency output under each resistance value is presented in FIG. 17. As expected, Fₒᵤₜ varies monotonically with respect to Rₛ and also demonstrates a saturating response consistent with equation 11.

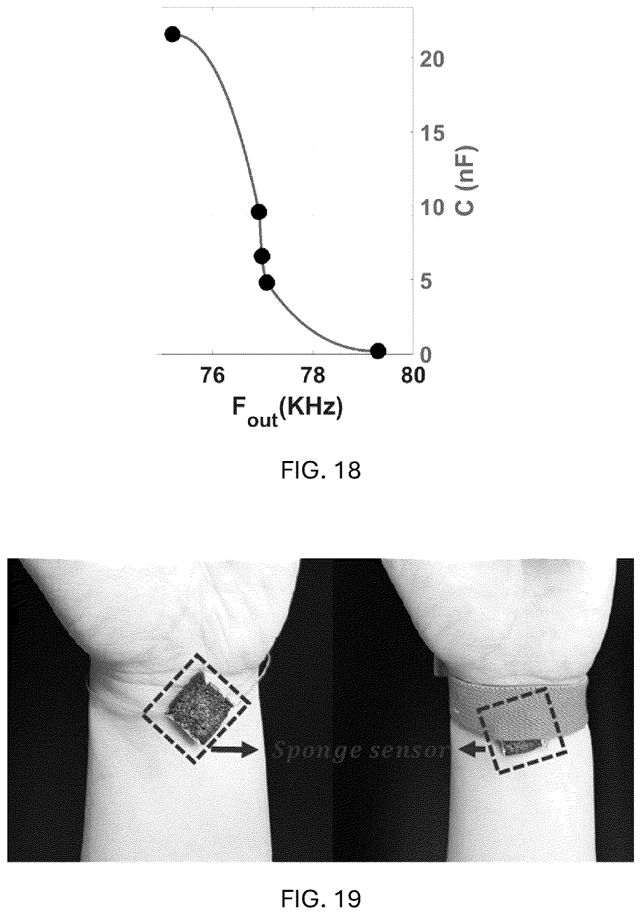

Subsequently, the switch S was turned ON to measure the impedance due to C_{L}. In this configuration, Rₛ was held at a constant value of 14.67 kΩ while varying C over the range 1.66 nF to 21.63 nF. The resulting measurements for each capacitance value are shown in FIG. 18. The response shows a “dead-zone” where changes in C does not lead to a change in Fₒᵤₜ or the converter frequency remains locked at 77 KHz. This “dead-zone” is characterized by the range of capacitance values where the impedance is centered about Rₛ=14.67 kΩ.

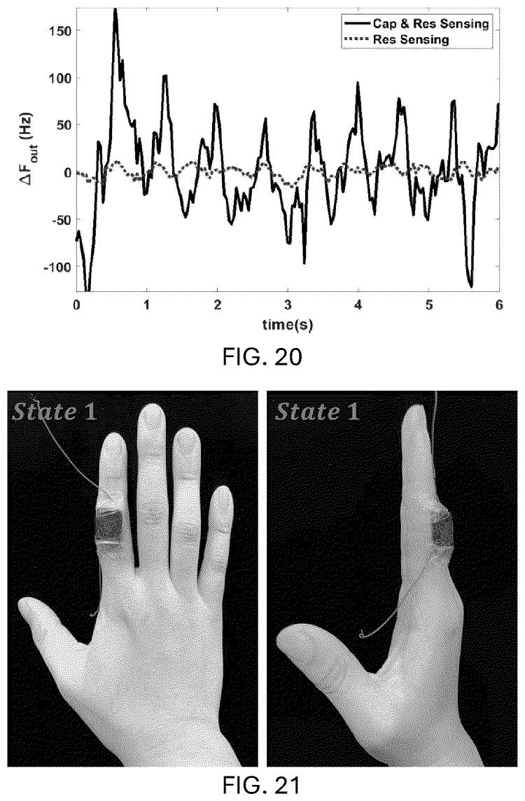

Radial Pulse Sensing—In a next series of experiments, a sponge transducer was positioned on a subject's wrist as shown in FIG. 19 (left side) and a wristband was tightly wrapped over the transducer (right side of FIG. 19) to provide secure and consistent contact for stable recording. A constructed implementation of the ITFC circuit 800 was used to sense the radial artery pulse of the subject. The sponge transducer used in this experiment was fabricated using porous polydimethylsiloxane (PDMS) cubes coated with a conductive polymer PEDOT: PSS as described above. The same experiment was performed twice, during which ITFC circuit 800 was programmed in both resistive-only and resistive & capacitive sensing modes. In both sensing modes, the external voltage source V₀ was set to 0.11 V. FIG. 20 plots the recorded waveform when measuring just R_{L} and when measuring R_{L} and C_{L}. It is s important to note that the recorded signals are modulated as the output frequency of the ITFC circuit 800 system changes in response to the variations in the sponge transducer's electrical properties. To better visualize the modulated signals, the baseline frequencies have been removed. Both waveforms clearly show the pulse signals corresponding to a heart rate of 108 beats per minute (bpm). Comparing the results obtained from both sensing modes, it is evident that the sensitivity is significantly boosted when sensing both the resistive and capacitive changes of the transducer. This improvement in sensitivity allows for more accurate and reliable detection of radial pulse signals.

Thus, in some embodiments, the ITFC 800 may be used in connection with one or more transducers 406 to as part of a pulse detector.

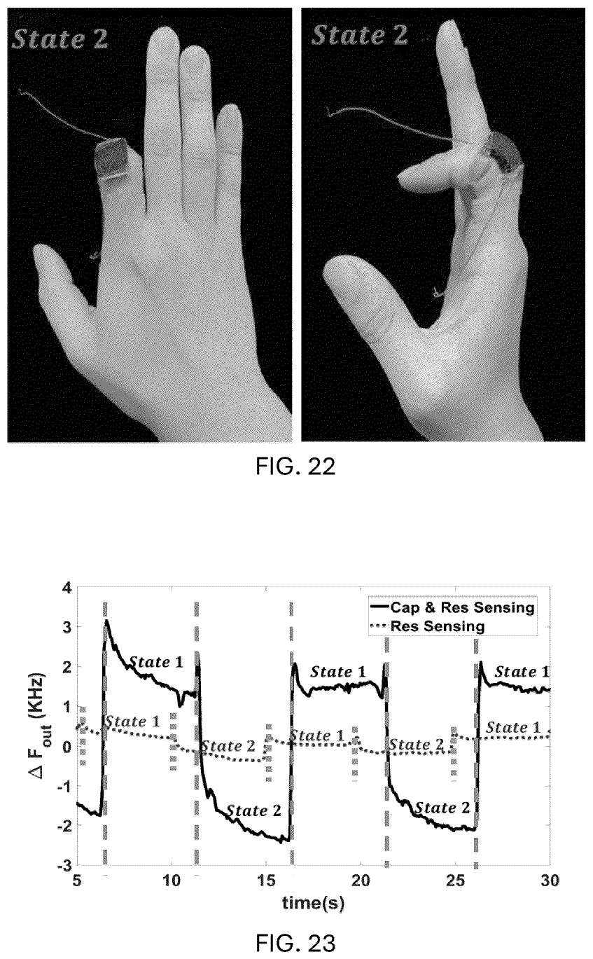

Gesture e Tracking Application A sponge transducer and the ITFC circuit 800 are used in some embodiments as part of a gesture tracking device, such as to sense the motion of the human finger. FIG. 21 shows two views of the placement of the sponge transducer 406 on a human finger joint in a straight position. FIG. 22 shows two views of the placement of the sponge transducer 406 on the same human finger joint in a bent position. The transducer 406 is connected to the ITFC circuit 800. In the straight position (FIG. 21), the sponge sensor maintains its original shape, while bending the finger (FIG. 22) causes the sponge transducer 406 to stretch, resulting in an increase in resistance and a decrease in capacitance. These changes in electrical properties are measured by the ITFC circuit 800.

In this example, the external voltage source V₀ was set to 0.11 V. The finger was consecutively bent (FIG. 22) and unbent (FIG. 21) within a 5-second time window. This was performed with the ITFC circuit 800 configured in both the resistive sensing mode and the resistive and capacitive sensing mode. The recorded gesture signal under both sensing modes is presented in FIG. 23 where the finger straight and bending regions are labeled accordingly. It is important to note that the output frequency baselines have been removed to provide a clearer visualization of the sensitivities under both sensing modes.

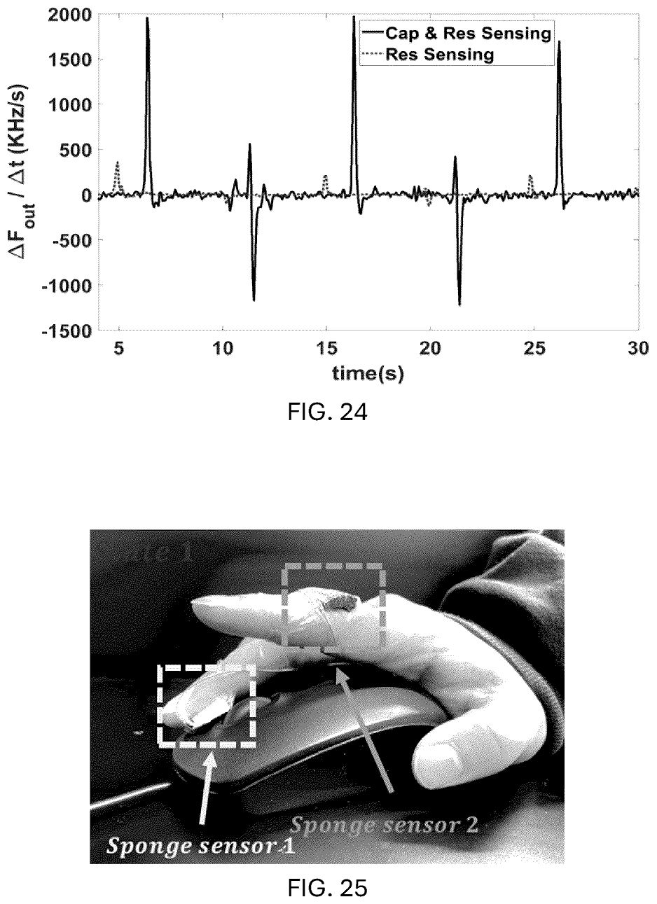

From the experimental results shown in FIG. 23, it is evident that when both resistive and capacitive changes are recorded, the sensitivity is significantly higher compared to sensing only the resistive property. The ability to capture both resistance and capacitance changes enhances the system's sensitivity, allowing for more precise and accurate detection of finger motion. For a more direct comparison of sensitivity under both sensing modes, FIG. 24 provides an illustration of a first-order derivative of the FIG. 23 result. It demonstrates that sensing both resistance and capacitance changes yields approximately 10 times higher sensitivity compared to sensing only resistance changes.

Thus, in some embodiments, the ITFC 800 may be used in connection with one or more transducers 406 to as part of a gesture tracking device. For example, the transducer(s) may be mounted in a wearable, such as a glove, a brace, a sleeve, etc., and be connected to detect motion/gestures based on the response of the transducer(s) to the wearers motions/gestures as detected by the ITFC.

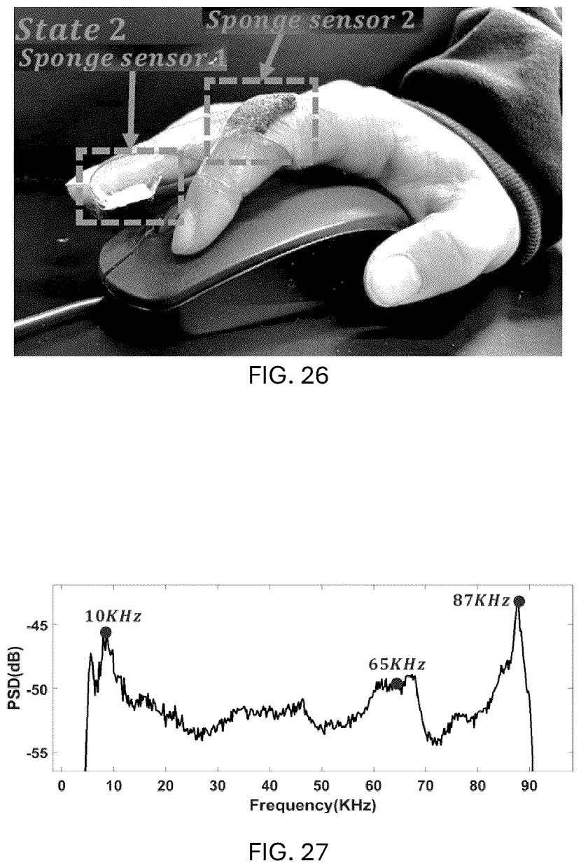

Multi-sensor experiment & Frequency-multiplexing—Since the baseline frequency of the converter can be set using the voltage V₀, it is possible to operate multiple sensor/transducers in a frequency multiplexed manner. In this way, the sensors can transmit the sensed information (impedance changes) over a common physical communication channel. Note that this communication channel could be a wire, wireless, or using the body-channel. Frequency multiplexing measurement has been shown using an experimental setup shown in FIGS. 25 and 26. Two sponge transducers were attached to different fingers are connected to separate prototyped ITFC circuits 800 whose outputs are multiplexed over a single transmission link. The transmission bandwidth is set by the VCO output frequency range, which is determined by resistor R_{osc}, as explained above. In this example R_{osc} was chosen to be 1 MΩ, achieving a bandwidth of 108 kHz.

The external voltage sources V₀ were set to 0.11 V and 0.24 V to bias the output frequency baseline at 85 kHz and 60 KHZ, respectively. Both prototyped systems were set to the resistive and capacitive sensing modes. As shown in FIGS. 25 and 26, the hand motion detected was two fingers individually clicking a mouse. FIG. 25 shows that only fingertip sensor 1 is active and observes the finger pressing activity. FIG. 26 shows that the finger joint-attached sponge sensor 2 detects finger bending activity.

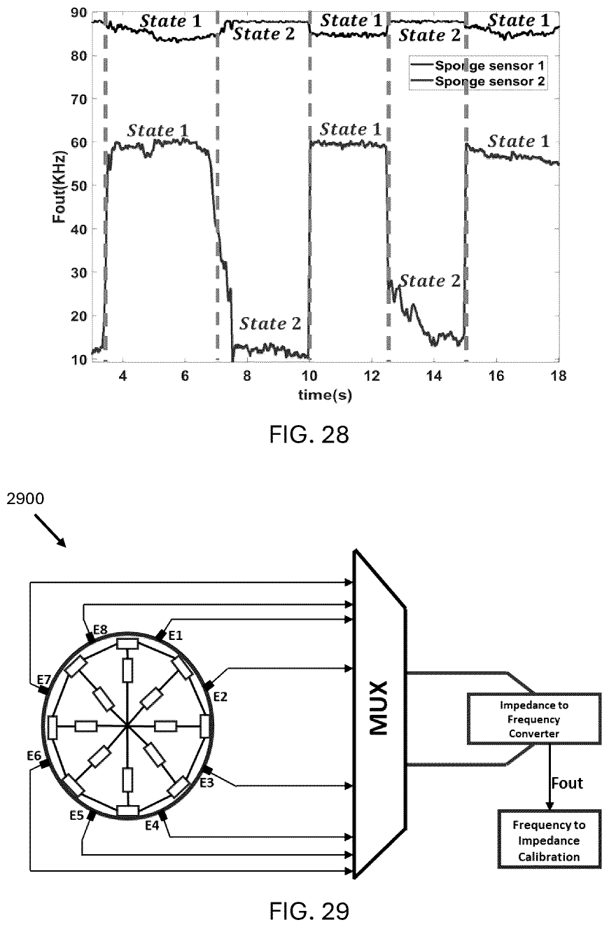

The multiplexed square wave output was collected using a Keithley DAQ6510 data acquisition system at a sampling rate of 200 kHz. FIG. 27 shows a power spectrum density plot of the multiplexed signal, from which we can discern both activity patterns. A peak at harmonics of 87 kHz representing the signal collected from finger pressing activity. Note that the finger bending activity has a high output frequency variation, so two peaks of 10 KHz and 65 kHz showing activity on & off were detected. The multiplexed square waves were then separated into two sections based on a 70 KHZ cutoff frequency. The frequencies of these two sections were calculated with a sampling window of 2.5 ms and plotted in FIG. 28, where we can clearly visualize the two types of motion, shown in FIGS. 25 and 26. The bending activity exhibits higher sensitivity than the pressing activity which could be attributed to the asymmetry in sensing changes in R_{L} and C_{L} when the transducer 406 is subjected to compressive or tensile strain. Note that previous work has shown that for the sponge transducer, the resistance and capacitance change differently in response to compressive strain, tensile strain, and pressure. This attribute in conjunction with the proposed impedance-to-frequency conversion could therefore be used for designing sensitive multi-modal sensors.

When an analog multiplexer is used to switch the ITFC circuit across many electrodes, as shown in FIG. 29, the system can be used for electrical-impedance-tomography. In this embodiment, ITFC measures changes in body impedances as frequency counts which is then conveyed to a software for image reconstruction.

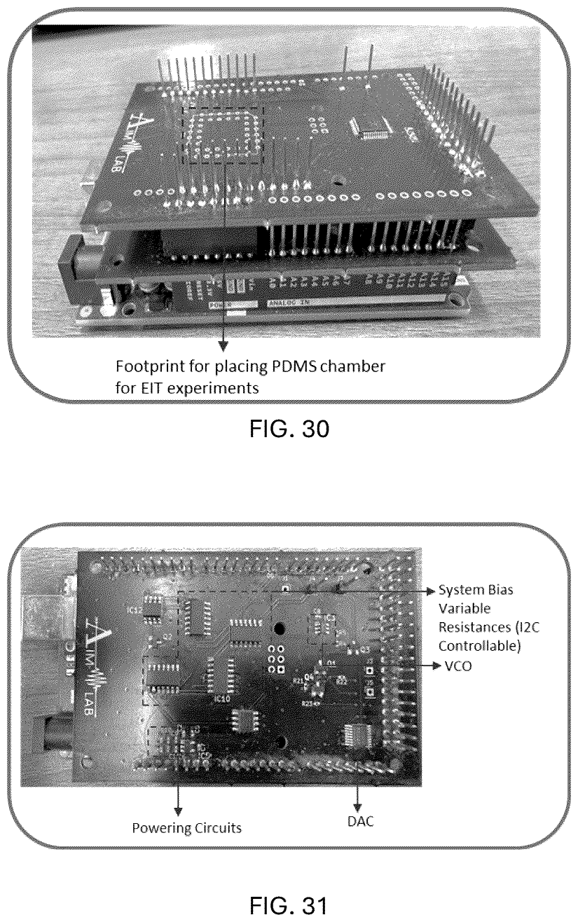

In some other embodiments, an ITFC circuit according to this disclosure may be used in a micro-EIT system 2900 shown in FIG. 29. The micro-EIT system 2900 uses a current reference source and a voltage-controlled oscillator (VCO) in a feedback configuration to modulate the sensor's impedance (due to its resistive & capacitive elements). The configuration thus locks the frequency Fₒᵤₜ such that the average current driven through the sensor impedance remains constant. The measurement or the operating frequency is a stable fixed-point of the circuit and hence is robust to small perturbation and noise when compared to the open-loop configuration. The lock-in frequency is determined by the transducer impedance, hence, the measurement frequency need not be determined a-priori and the dynamic range of the converter is determined by the dynamic range of the relaxation oscillator. The output of the ITFC is encoded as the frequency of a square-wave which can be viewed as a pulse-density digital code. Thus, the ITFC does not need an additional analog-to-digital (ADC) converter. Even though this type of encoding is not minimal, simply using a counter or digital low-pass filter can estimate a binary encoding of the frequency measurement. The energy footprint for such a counter could be less than 1 μW for a counter operating at 100 KHz (assuming 1 pJ/bit operation). FIGS. 30 and 31 are two photographs of a prototype micro-EIT system which has been developed using commercial-off-the-shelf (COTS) chipsets. The system can be used for at least three specific applications: (a) measuring the dynamical characteristics of a chemiresistor array which is used for sensing different volatile organic compounds; (b) to sense impedance changes across a multi-modal sensor array for measuring changes in mechanical pressure and strain; (c) to non-invasively measure the electrical activity of active biological tissues which includes-insect brains and organoids.

One example embodiment of the present disclosure is an EIT system, wherein the ITFC circuit is multiplexed across multiple electrodes and measuring impedance.

Another example embodiment is an EIT system, wherein different electrode pairs are connected to a separate ITFC circuit which wirelessly transmits the information using frequency-division multiplexing.

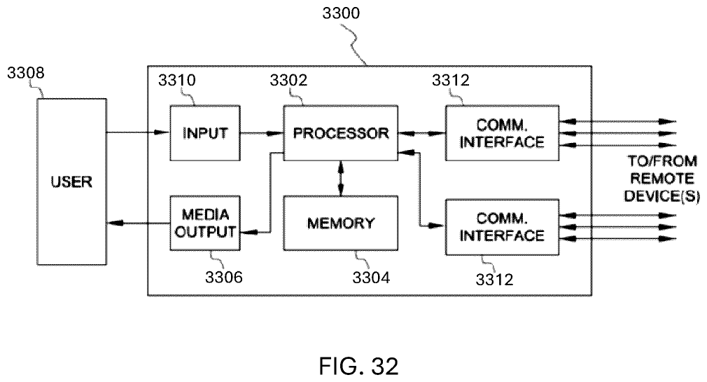

At least some embodiments of the present disclosure will include or at least be communicatively coupled to a computing device. For example, the computing device may be coupled to receive the output Fₒᵤₜ from the ITFCs in FIGS. 4, 6, and 8 and perform the determinations (e. g., impedance, resistance, and/or capacitance) described above or any other processing and display of the data or the results of calculations performed using the data. Moreover, the computing device may control the operation of the ITFC, such as by setting one or more voltage or current level for operation of the ITFC. FIG. 32 is an example configuration of a computing device 3300 that may be used in connection with the ITFCs described herein is shown. Moreover, in some embodiments, the ITFC and the computing device 3300 are integrally formed, such as by being parts of an integrated circuit, by being mounted on a common circuit board, by being part of a system on a chip, or the like. The computing device 3300 includes a processor 3302, a memory 3304, a media output component 3306, an input device 3310, and communications interfaces 3312. Other embodiments include different components, additional components, and/or do not include all components shown in FIG. 32.

The processor 3302 is configured for executing instructions. In some embodiments, executable instructions are stored in the memory 3304. The processor 3302 may include one or more processing units (e.g., in a multi-core configuration). As used herein, the term “processor” refers not only to integrated circuits, but also to a controller, a microcontroller, a microcomputer, a programmable loic controller (PLC), an application-specific integrated circuit, a graphic processing unit, and other programmable circuits. The memory 3304 may generally be or include memory element(s) including, but not limited to, computer readable medium (e.g., random access memory (RAM)), computer readable non-volatile medium (e.g., a flash memory), a floppy disk, a compact disc-read only memory (CD-ROM), a magneto-optical disk (MOD), a digital versatile disc (DVD) and/or other suitable non-transitory memory elements and is generally any device allowing information such as executable instructions and/or other data to be stored and retrieved. Such memory 3304 may generally be configured to store suitable computer-readable instructions that, when implemented by the processor 3302, configure, cause, or program the computing device 3300 to perform various functions described herein.

The media output component 3306 is configured for presenting information to user 3308. The media output component 3306 is any component capable of conveying information to the user 3308. In some embodiments, the media output component 3306 includes an output adapter such as a video adapter and/or an audio adapter. The output adapter is operatively connected to the processor 3302 and operatively connectable to an output device such as a display device (e.g., a liquid crystal display (LCD), organic light emitting diode (OLED) display, cathode ray tube (CRT), “electronic ink” display, one or more light emitting diodes (LEDs)) or an audio output device (e.g., a speaker or headphones).

The computing device 3300 includes, or is connected to, the input device 3310 for receiving input from the user 3308. The input device is any device that permits the computing device 3300 to receive analog and/or digital commands, instructions, or other inputs from the user 3308, including visual, audio, touch, button presses, stylus taps, etc. The input device 3310 may include, for example, a variable resistor, an input dial, a keyboard/keypad, a pointing device, a mouse, a stylus, a touch sensitive panel (e.g., a touch pad or a touch screen), a gyroscope, an accelerometer, a position detector, or an audio input device. A single component such as a touch screen may function as both an output device of the media output component 3306 and the input device 3310.

The communication interfaces 3312 enable the computing device 3300 to communicate with remote devices and systems, such as allowing communication between the controller 108 and the imaging device 102, the illumination and filtering subsystem 104, remote computing devices or servers (not shown), and the like. The communication interfaces 3312 may be wired or wireless communications interfaces that permit the computing device to communicate with the remote devices and systems directly or via a network. Wireless communication interfaces 3312 may include a radio frequency (RF) transceiver, a Bluetooth® adapter, a Wi-Fi transceiver, a ZigBee® transceiver, a near field communication (NFC) transceiver, an infrared (IR) transceiver, and/or any other device and communication protocol for wireless communication. (Bluetooth is a registered trademark of Bluetooth Special Interest Group of Kirkland, Washington; ZigBee is a registered trademark of the ZigBee Alliance of San Ramon, California.) Wired communication interfaces 3312 may use any suitable wired communication protocol for direct communication including, without limitation, USB, RS232, I2C, SPI, analog, and proprietary I/O protocols. In some embodiments, the wired communication interfaces 3312 include a wired network adapter allowing the computing device to be coupled to a network, such as the Internet, a local area network (LAN), a wide area network (WAN), a mesh network, and/or any other network to communicate with remote devices and systems via the network. Although two communication devices 3312 are shown, the computing device 3300 may include more or fewer computing devices.

It should be understood that in some embodiments the computing device 3300 does not include or use an input 3310 or a media output 3306 and a user 3308 may not directly interact with the computing device. Rather, the user 3308 (or another computing device) may only interact remotely with computing device 3300 through the communication interface 3312.

Moreover, in some embodiments the computing device 3300, or parts thereof, may not be a physical computing device local to the user 3308, but instead is cloud based. Thus, for example, the computing device 145 may be a cloud-based computing device or may be a physical computing device 3300 using cloud-based storage for all or part of its memory 3304, using cloud-based processing instead of local processing for some or all of its processing, or the like. Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. As used herein, the term “cloud computing” and related terms, e.g., “cloud computing devices” refers generally to a computer architecture allowing for the use of multiple heterogeneous computing devices for data storage, retrieval, and processing. The heterogeneous computing devices may use a common network or a plurality of networks so that some computing devices are in networked communication with one another over a common network but not all computing devices. In other words, a plurality of networks may be used to facilitate the communication between and coordination of all computing devices.

In some embodiments, the computing device 3300 may be embodied on or may include a desktop computer, a laptop computer, a tablet computer, a mobile phone, a microcontroller, a single board computer, or any other device operable to function as the computing device 3300 described herein.

The examples described herein include compact, ultra-low power, impedance-to-frequency converters suitable for use with a wearable sponge transducer. By monitoring changes in resistance and capacitance induced by mechanical deformation of the sponge transducer, the proposed systems have been shown to exhibit significantly higher sensitivity compared to monitoring just the change in resistance.

The example systems operates at ultra-low bias currents and eliminate the need for sinusoidal current source generation and signal amplification stages. This makes the described ITFC circuit suitable for miniaturized sensing platforms that are battery-powered or powered remotely. It has also been demonstrated that the converter can facilitate direct frequency multiplexing of the measured impedance values. This feature makes the design scalable to the large number of transducers. The ITFC circuit may thus be used for a large array of wearable transducers. In some other embodiments, the ITFC circuit may be implemented using application-specific integrated circuits (ASICs) to thereby provide further improvement in system energy-efficiency.

This written description uses examples to disclose the invention, including the best mode, and also to enable any person skilled in the art to practice the invention, including making and using any devices or systems and performing any incorporated methods. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e. g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A impedance-to-frequency converter (ITFC) circuit without a sinusoidal current source, the ITFC circuit comprising:
a current reference circuit including a first reference terminal and a second reference terminal, the second reference terminal connected to a first ITFC terminal configured for connection to a first terminal of a transducer, wherein a first voltage at the first reference terminal has a known relationship with a second voltage at the second reference terminal;
an oscillator circuit including an oscillator output and an input connected to the first reference terminal of the current reference circuit and configured to output an output signal whose frequency is determined at least in part on the first voltage at the first reference terminal; and
a switch circuit including a switch input connected to the oscillator output, the switch circuit coupled across the first terminal of the transducer and a second terminal of the transducer and configured to open and close a connection between the first terminal of the transducer and the second terminal of the transducer in response to the output signal from the oscillator circuit, wherein the second voltage at the second reference terminal of the current reference circuit varies based on whether the connection between the first terminal of the transducer and the second terminal of the transducer in the switch circuit is closed or open and one or both of a resistance and a capacitance of the transducer.

2. The ITFC circuit of claim 1, wherein the oscillator circuit includes an ITFC output to output the output signal to a computing device.

3. The ITFC circuit of claim 1, wherein the current reference circuit comprises a proportional to absolute temperature (PTAT) circuit.

4. The ITFC circuit of claim 3, wherein the current reference circuit further comprises a reference resistor that sets a constant potential difference between the first voltage on the first terminal and the second voltage on the second terminal.

5. The ITFC circuit of claim 1, wherein the oscillator circuit comprises a relaxation oscillator.

6. The ITFC circuit of claim 5, further comprising an oscillator resistor coupled between the oscillator input and the first reference terminal of the current reference, wherein the frequency of the oscillator circuit output signal is determined by the first voltage at the first reference terminal and a resistance of the oscillator resistor.

7. The ITFC circuit of claim 1, further comprising an active shield module configured to cancel out parasitic capacitances between the first terminal of the transducer and ground and between the first terminal and the second terminal of the transducer.

8. The ITFC circuit of claim 7, wherein the active shield module comprises a buffer.

9. The ITFC circuit of claim 1, further comprising a second ITFC terminal configured for connection to the second terminal of the transducer to apply a fixed third voltage to the second terminal of the transducer.

10. The ITFC circuit of claim 1, wherein the circuit is implemented in a wearable sensor device.

11. A method of converting an impedance of a transducer to a frequency, the method comprising:
providing a first voltage to an oscillator circuit, the first voltage having a known relationship to a second voltage;
generating a square wave signal with the oscillator circuit, the square wave signal having a frequency determined at least in part by the first voltage; and
opening and closing a switch coupled across a first terminal and a second terminal of the transducer in response to the square wave signal generated by the oscillator circuit to vary the second voltage as a function of the impedance of the transducer, the first terminal of the transducer being connected to a fixed third voltage.

12. The method of claim 11, further comprising outputting the square wave signal from the oscillator circuit to a computing device.

13. The method of claim 12, further comprising determining, by the computing device, the impedance of the transducer, a resistance of the transducer, or a capacitance of the transducer based on the received square wave signal from the oscillator circuit.

14. The method of claim 11, wherein providing the first voltage to the oscillator circuit is performed by a proportional to absolute temperature (PTAT) circuit.

15. The method of claim 11, wherein the oscillator circuit comprises a relaxation oscillator.

16. The method of claim 15, wherein generating the square wave signal with the oscillator circuit comprises generating the square wave signal having a frequency determined at least in part by the first voltage by the first voltage and a resistance of an oscillator resistor coupled between the oscillator input and the first voltage.

17. A wearable sensor device comprising:
a transducer operable to change resistance and capacitance in response to mechanical strain applied to the transducer; and
an impedance-to-frequency converter (ITFC) circuit without a sinusoidal current source coupled to the transducer, the ITFC configured to continuously output a signal whose frequency is bases on an impedance, a resistance, or a capacitance of the transducer.

18. The wearable sensor device of claim 17, further comprising a processor couple to the ITFC circuit to receive the signal and to determine the impedance, the resistance, or the capacitance of the transducer based on the signal.

19. The wearable sensor device of claim 17, wherein the transducer comprises a poly(3, 4-ethylene dioxythiophene) polystyrene sulfonate (PEDOT: PSS) sponge transducer.

20. The wearable sensor device of claim 17, wherein the ITFC circuit comprises a voltage-controlled relaxation oscillator and a proportional-to-temperature (PTAT) current reference that sets an oscillation frequency of the oscillator according to the impedance of the transducer.
